(19) United States
(12) Patent Application Publication
(10) Pub. No.: US 2012/0168943 A1
(43) Pub. Date: Jul. 5, 2012

(54) PLASMA TREATMENT ON SEMICONDUCTOR WAFERS

(75) Inventors: Kah Wee Gan, Maur (MY); Yonggang Jin, Singapore (SG); Anandan Ramasamy, Singapore (SG); Yun Liu, Singapore (SG)

(73) Assignee: STMICROELECTRONICS PTE. LTD., Singapore (SG)

(21) Appl. No.: 12/982,719

(22) Filed: Dec. 30, 2010

(51) Int. Cl. H01L 23/485; H01L 21/50

(52) U.S. Cl. 257/738; 438/107; 257/783; 257/E21.499; 257/E23.02; 257/E23.021

(57) ABSTRACT

A semiconductor package and method of forming the same is described. The semiconductor package is formed from a semiconductor die cut from a semiconductor wafer that has a passivation layer. The semiconductor wafer is exposed to ionized gas causing the passivation layer to roughen. The semiconductor wafer is cut to form a plurality of semiconductor dies each with a roughened passivation layer. The plurality of semiconductor dies are placed on an adhesive layer to form a reconstituted wafer, and an encapsulation layer is formed enclosing the adhesive layer and the plurality of semiconductor dies. The passivation layer is removed and the semiconductor package formed includes electrical contacts for establishing electrical connections external to the semiconductor package.

### BACKGROUND

1. Technical Field

This description generally relates to a reconstituted semiconductor wafer with semiconductor chips embedded within that have been treated in a plasma chamber.

2. Description of the Related Art

Typically, after a semiconductor chip is manufactured, it must further be processed and encapsulated in a package that functions to protect the chip and to establish electrical connections from the chip to the external environment. Two methods by which a semiconductor chip may be packaged include fan-in and fan-out packages.

Fan-in methods of semiconductor packaging usually result in a semiconductor package that is essentially the same size as the semiconductor chip. This is because fan-in methods use wafer level packaging techniques that build the semiconductor package on top of the semiconductor wafer after the chips have been created. Due to the proximity of each semiconductor chip to one another on the wafer there is limited space for making electrical connections laterally, so packages are built vertically. As a result, and because of the chip size, a limited amount of space is available for electrical contacts.

Fan-out methods of semiconductor packaging are not restricted by the size of the semiconductor chip in determining the number of electrical contacts to the external environment. This is because fan-out semiconductor packages have a larger footprint area than that of the semiconductor chips within. Typically, during fan-out methods of semiconductor packaging, the semiconductor chips are cut from the semiconductor wafer after the chips are manufactured. The cut chips are subsequently placed on an adhesive layer and formed into a reconstituted wafer. Since the semiconductor chips were not formed on the reconstituted wafer initially, they must be either permanently or temporarily affixed to the surface to form the reconstituted wafer.

Several known ways of adhering chips to a surface include adhesive glue, adhesive tape, epoxy resin, etc. Even with known methods of affixing chips to a reconstituted wafer, however, there is a possibility that the chips will move due to various stresses and forces during the packaging process. For example, the upper surface of the semiconductor wafer is usually a passivation layer that may be made of various different types of materials. Each type of passivation layer may be designed to adhere to different types of adhesive layers during semiconductor chip packaging. As a result, when the chip packaging reaches an encapsulation process, chips that are not well adhered may be knocked loose, resulting in what is known as flying dies (i.e., flying chips). Flying dies are undesirable because the number of viable semiconductor packages produced is reduced and the cost of manufacturing semiconductor packages is increased.

### BRIEF SUMMARY

A method of manufacturing a semiconductor package is disclosed. A semiconductor wafer with a passivation layer is formed. The wafer has a plurality of semiconductor chips formed thereon. The passivation layer is exposed to ionized gas, which causes a surface of the passivation layer to roughen. After the passivation layer is exposed to ionized gas and the semiconductor wafer is cut into a plurality of semiconductor chips, at least one of the plurality of semiconductor chips is placed on an adhesion layer with the passivation layer of the chip making contact with the adhesion layer.

A semiconductor package with a semiconductor chip is also disclosed. The semiconductor chip is formed within the semiconductor package. The semiconductor chip has a passivation layer formed on one side of the chip. The passivation layer is subjected to ionized gas before the semiconductor package is formed. An encapsulation layer encloses the semiconductor chip except on the passivation layer side. The passivation layer has a roughened surface as a result of being exposed to the ionized gas.

An integrated chip packaging system for manufacturing semiconductor packages is also disclosed. The integrated chip packaging system includes a cutting device for cutting a semiconductor wafer into a plurality of semiconductor chips. The integrated chip packaging system also includes an ionization chamber for exposing a passivation surface of the semiconductor wafer to ionized gas. An affixing device is included in the integrated chip packaging system and is configured to affix at least one of the plurality of semiconductor chips to an adhesion layer of a reconstituted wafer. The semiconductor chips on the reconstituted wafer are encapsulated and formed into individual semiconductor packages.

### BRIEF DESCRIPTION OF THE SEVERAL VIEWS OF THE DRAWINGS

The foregoing and other features and advantages of the present disclosure will be more readily appreciated as the same become better understood from the following detailed description when taken in conjunction with the accompanying drawings.

FIG. 1 is an isometric view of a semiconductor package according to one embodiment of the present disclosure.

FIG. 2 is a flowchart of a process according to the present disclosure for creating a reconstituted wafer that has a plurality of packaged semiconductor chips.

FIG. 3 is a top view of a semiconductor wafer having semiconductor chips formed thereon.

FIG. 4 is a side view of a plasma etching chamber used to etch a passivation layer formed on a semiconductor wafer according to one embodiment.

FIG. 5A is a side view of a semiconductor wafer before processing in the plasma etching chamber.

FIG. 5B is a side view of the semiconductor wafer of FIG. 5A after processing in the plasma etching chamber.

FIG. 6A is a side view of a first step in forming a reconstituted wafer using individually cut chips from the semiconductor wafer that has been processed in the plasma etching chamber shown in FIG. 4.

FIG. 6B is a side view of a next step in forming the reconstituted semiconductor wafer by forming an encapsulation layer over the individually cut semiconductor chips.

FIG. 6C is a side view of a next step in forming the reconstituted semiconductor wafer by removing the adhesive layer.

FIG. 6D is a side view of a next step in forming the reconstituted semiconductor wafer with the passivation layer and portions of the encapsulation layer removed.

FIG. 7 is a side view of a semiconductor package formed from an encapsulated chip cut from the reconstituted wafer previously formed in FIGS. 6A-6D.

### DETAILED DESCRIPTION

In the following description, certain specific details are set forth in order to provide a thorough understanding of various aspects of the disclosure. However, one skilled in the art will understand that the disclosure may be practiced without these specific details. In some instances, well-known structures and methods of forming the structures associated with the semiconductor package have not been described in detail to avoid obscuring the descriptions of the aspects of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

Reference throughout this specification to “one aspect” or “an aspect” means that a particular feature, structure, or characteristic described in connection with the aspect is included in at least one aspect. Thus, the appearances of the phrases “in one aspect” or “in an aspect” in various places throughout this specification are not necessarily all referring to the same aspect. Furthermore, the particular features, structures, or characteristics may be combined in any suitable manner in one or more aspects of the present disclosure.

In the drawings, identical reference numbers identify similar features or elements. The size and relative positions of features in the drawings are not necessarily drawn to scale.

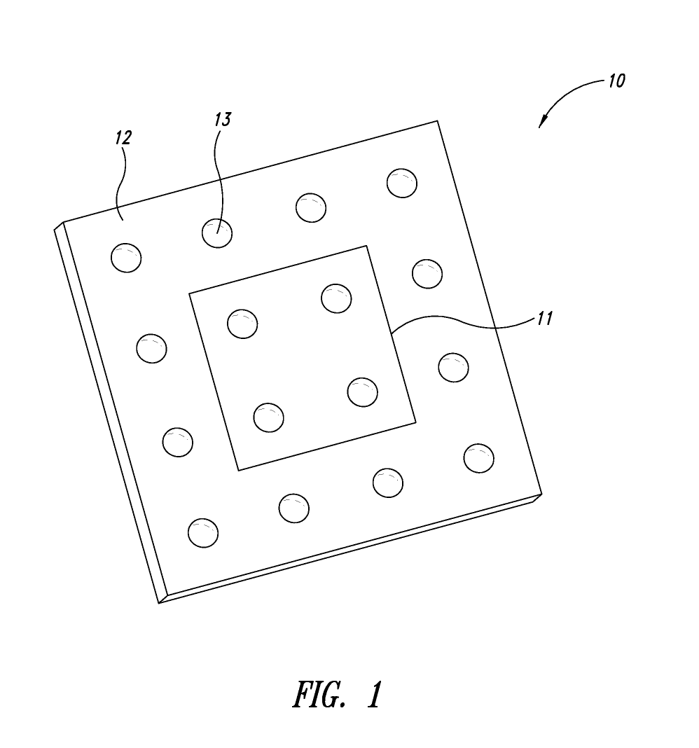

FIG. 1 shows a semiconductor package 10 according to the present disclosure. The semiconductor package 10 has a semiconductor chip area 11, a fan-out layer area 12, and electrical contacts 13 formed on both the semiconductor chip area 11 and the fan-out layer area 12. The semiconductor chip area 11 and fan-out area 12 identify where in the semiconductor package 10 the chip is located. The semiconductor package 10 may also have other elements included therein. These additional elements may be passive elements such as resistors, capacitors, and inductors, connective substrates, and other connective elements, such as bonding wires or the like.

The electrical contacts 13 may be conductive metal, such as solder balls, used to connect the semiconductor package 10 to another device, including a printed circuit board (not shown). The electrical contacts 13 are preferably attached to the semiconductor package 10 using a solder reflow paste or other temporary adhesive. The semiconductor package 10 is subsequently affixed to another device using a solder reflow process in which the electrical contacts 13 melt and attach to other electrical contacts (not shown) attached on the other device.

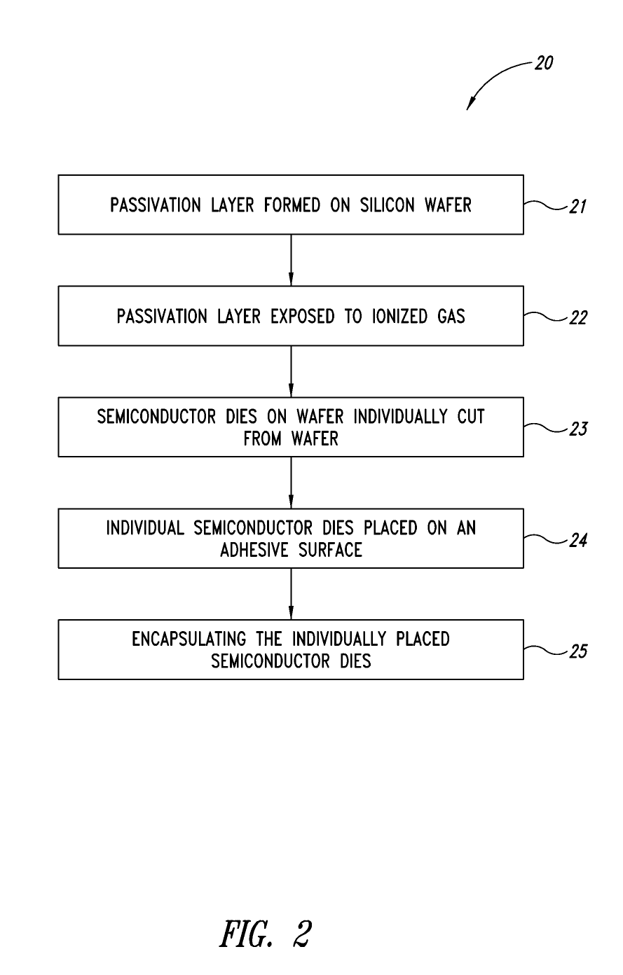

The semiconductor package 10 is typically formed from a reconstituted wafer having many semiconductor packages manufactured in a batch processing environment. During manufacturing, the various layers and components of the semiconductor package 10 are formed on many semiconductor areas at once to improve throughput and lower the cost of manufactured semiconductor packages. FIG. 2 shows a process flow 20 for forming a reconstituted wafer that has a plurality of semiconductor chips placed thereon.

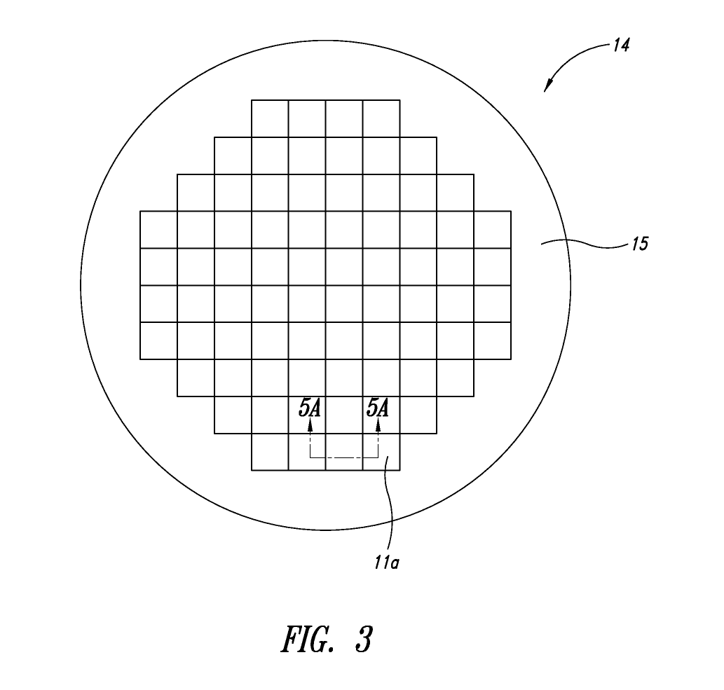

Beginning at step 21 of the process flow 20 shown in FIG. 2, a passivation layer is formed on a silicon wafer having semiconductor chips. For example, FIG. 3 shows a semiconductor wafer 14 with semiconductor chips 11a that have a passivation layer 15 formed on the semiconductor wafer 14. The passivation layer 15 may be formed of an insulating material, such as silicon nitride (Si₃N₄), silicon dioxide (SiO₂), an oxynitride compound, or the like. Further, the passivation layer 15 may be formed using plasma-enhanced chemical vapor deposition, low-pressure chemical vapor deposition, or the like.

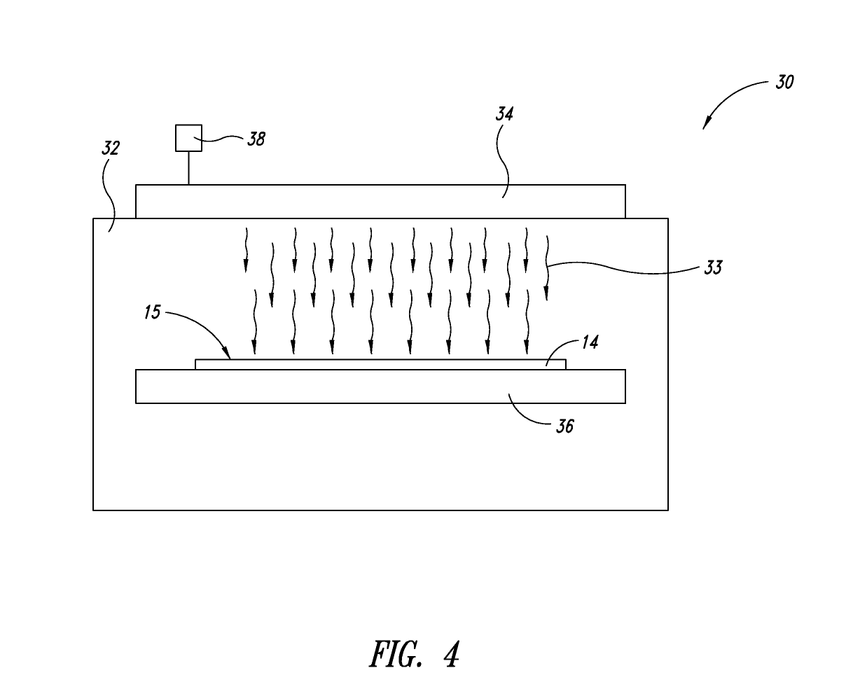

Moving to step 22 of the process flow 20, the passivation layer 15 is exposed to ionized gas, which results in a roughened passivation layer. FIG. 4 shows a plasma etching chamber 30 according to one embodiment. The plasma etching chamber 30 has a chamber 32 for receiving and holding the semiconductor wafer 14 on a wafer chuck 36. The semiconductor wafer 14 may be held in place by the wafer chuck 36 to remain stable during the plasma etching process. The plasma etching chamber 30 also has an upper portion 34 and a power source 38. According to one aspect of the present embodiment, the upper portion 34 is located outside the chamber 32. Alternatively, the upper portion 34 may be located inside the chamber 32 depending on the type of plasma etching carried out in the plasma etching chamber 30. The power source 38 may be attached to both the wafer chuck 36 and the upper portion 34.

The plasma etching chamber 30 exposes the passivation layer 15 to ionized gas, which interacts with the passivation layer 15 material causing a roughened surface to develop. According to one embodiment, the passivation layer 15 is etched using reactive-ion etching (“RIE”). When the plasma etching chamber 30 uses RIE, the chamber 32 is filled with a gas at low pressure. For example, the gas may be carbon tetrafluoride (CF₄, also known as tetrafluoromethane) or oxygen (O₂). When the power supply 38 is activated, a voltage is applied across the wafer chuck 36 and the upper portion 34. To form the voltage potential, the upper portion 34 may be connected to ground or is negatively charged, whereas the wafer chuck 36 is positively charged.

When the voltage is applied across the upper portion 34 and the wafer chuck 36, an electric field is produced inside the chamber 32 that causes the gas inside the chamber 32 to ionize, or become a plasma. In the case where CF₄ is used as the gas, negatively charged ions 33 (fluorine, F⁻ in this case) are produced within the electric field and accelerated from the upper portion 34 to the wafer chuck 36. The negatively charged ions 33 accelerate toward the wafer chuck 36 and bombard the passivation layer 15 of the semiconductor wafer 14, which causes an upper surface of the passivation layer 15 to roughen. Instead of using CF₄ gas, O₂ gas or other gases that produce negative ion particles in an electric field may be used in the plasma etching chamber 32.

In an alternative embodiment, the passivation layer 15 is etched using inductive coupled plasma etching (“ICP”). In ICP etching, the upper portion 34 of the plasma etching chamber 30 includes an inductive coil (not shown) connected to the power source 38 and a top plate (not shown), such as a quartz window, which permits an induced electric field to enter the chamber 32 while protecting the chamber 32 from possible stray ions emitted from the inductive coil during operation. The inductive coil used in ICP may be a flat coil (planar) wrapping in on itself within a plane or a helix coil laterally wrapping around an axis. The wafer chuck 36 is not connected to the power source 38 using ICP plasma etching. As a result, the power source 38 supplies a voltage across the inductive coil inside the upper portion 34, which causes an induced electric field to enter the chamber 32 below the upper portion 34.

In the ICP technique, the chamber 32 is filled with a gas, such as CF₄ or O₂, which ionizes in the presence of the electric field generated by the inductive coil inside the upper portion 34, similar to the ionized gas in the RIE technique. Although the wafer chuck 36 is not connected to the power source 38 in the ICP technique, it may be connected to a matching power source (not shown) to positively charge the wafer chuck 36. Once the wafer chuck 36 is positively charged, the negative ions 33 produced in the plasma in the chamber 32 are accelerated toward the wafer 14. The negatively charged ions 33 bombard the passivation layer 15 and cause an upper surface of the passivation layer 15 to roughen.

Using both the RIE and ICP techniques does not completely etch away the passivation layer 15. Rather, only an upper surface of the passivation layer 15 is etched and roughened. Additionally, any plasma etching technique in which the upper layer of the passivation layer 15 is roughened is considered an equivalent to the RIE and ICP techniques.

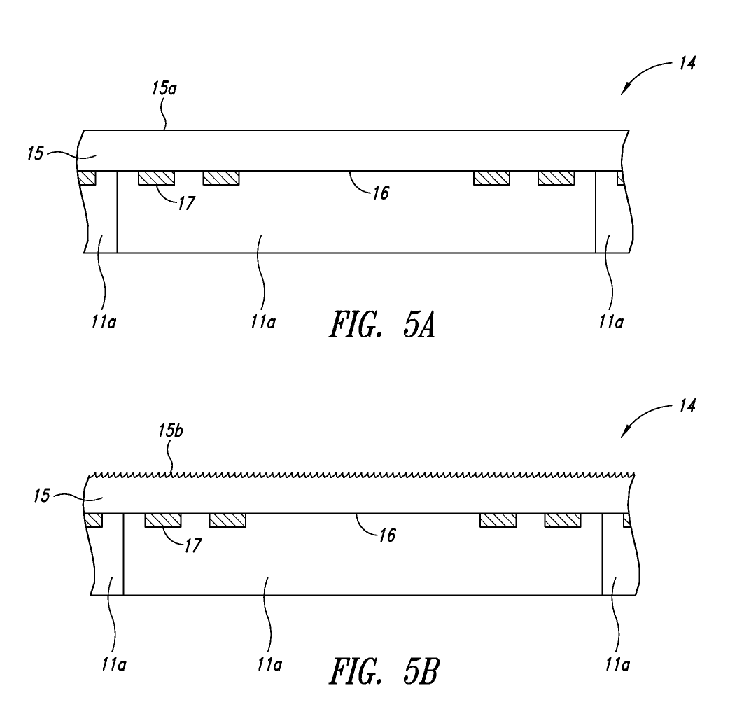

FIG. 5A shows an enlarged side view of the semiconductor chip 11a before the plasma etching process described with regard to FIG. 4. FIG. 5B shows an enlarged view of the semiconductor chip 11a after the plasma etching process described with regard to FIG. 4. In both FIGS. 5A and 5B, the semiconductor chip 11a has an active side 16 and contact pads 17. The contact pads 17 are locations where electrical connections to the external circuits can be made. The passivation layer 15 has an upper smooth surface 15a that is substantially smooth and flat as shown in FIG. 5A before the plasma etching process. After the plasma etching process, the passivation layer 15 becomes roughened and has an upper roughened surface 15b as shown in FIG. 5B. The actual roughness of the upper roughened surface 15b may not be as uniform as or shaped like the upper roughened surface 15b as illustrated in FIG. 5B. The jagged surface shown in FIG. 5B of upper roughened surface 15b is for illustrative purposes only and should not be interpreted to limit the scope of the present disclosure or claims to the particular pattern or roughness shown.

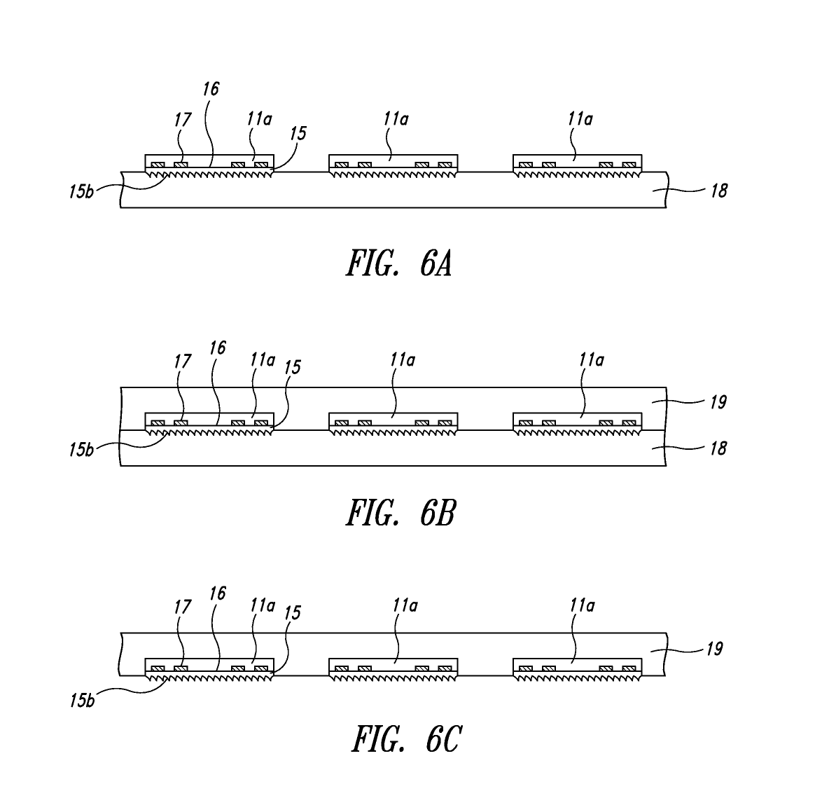

After the passivation layer 15 has been roughened by the etch, the semiconductor wafer 14 is cut using a saw (not shown) to form individual semiconductor chips 11a as indicated in step 23 of FIG. 2. The semiconductor wafer 14 may be cut using any known techniques or their equivalents. After the semiconductor wafer 14 is cut, the individual semiconductor chips 11a are placed on an adhesive surface as indicated in step 24 of FIG. 2 and shown in FIG. 6A. The individually cut semiconductor chips 11a are flipped and placed with the upper roughened surface 15b making contact with an adhesive layer 18.

According to one embodiment, the adhesive layer 18 is a reconstitution tape or another type of adhesive tape used for securing semiconductor and other electrical components temporarily. In an alternative embodiment, the adhesive layer 18 may comprise a non-adhesive solid layer (not shown) covered by a layer of adhesive (not shown), such as adhesive glue on top of a solid metal or ceramic layer. The semiconductor chip 11a would similarly be placed with the upper roughened surface 15b of the passivation layer 15 in direct contact with the adhesive glue.

After the individual semiconductor chips 11a are placed on the adhesive layer 18, an encapsulation layer 19 is formed, enclosing the semiconductor chips 11a, as indicated in step 25 and shown in FIG. 6B. In one embodiment, the encapsulation layer 19 is a molding layer made of a molding material such as a composite that may include an epoxy resin, a hardener, a catalyst, or the like. The encapsulation layer 19 is further made of a material that is flexible yet tolerant to mechanical stresses.

The encapsulation layer 19 may be formed by injecting a liquid encapsulation material onto the top of the adhesive layer 18 and semiconductor chips 11a. In the prior art, if the semiconductor chips 11a were not secure because the adhesion is not strong enough, for example because the die was not completely flush with the adhesive, the die was not planar with the adhesive, the adhesive had some prior debris thereon, or the like, the force from the injected encapsulation material might have pushed the semiconductor chips 11a out of place, causing the die to move from the location in which it was placed. As a result, in the prior art, the moved semiconductor chip 11a cannot be used in the final package. Worse yet, if the dislodged die has landed in an area with another semiconductor chip, neither area can be used to create a working semiconductor package. Accordingly, enhancing the adhesive properties of the semiconductor chips 11a by plasma etching the passivation layer 15 to create the upper roughened surface 15b reduces dislodging of dies from the adhesive layer 18 and increases semiconductor package throughput.

Once the encapsulation layer 19 is formed, as seen in FIG. 6B, the adhesive layer 18 is removed, as seen in FIG. 6C. In one embodiment, the adhesive layer 18 may be removed physically, such as by pulling the adhesive layer 18 away from the encapsulation layer 19 and the semiconductor chips 11a. In an alternative embodiment, the adhesive layer 18 is heated to a temperature at which point adhesive properties of the adhesive layer 18 are lost and the adhesive layer 18 may fall off. Any other known way of removing the adhesive layer 18 is acceptable, such as grinding the adhesive layer 18 away, etc.

As seen in FIG. 6D, once the passivation layer 18 is removed, the active side 16 of the semiconductor chip 11a is exposed. In one embodiment, the passivation layer 15 is ground down using chemical mechanical polishing/planarization (“CMP”) or the like. Grinding down the passivation layer 15 also may remove a portion of the encapsulation layer 19, but it is not necessary to make the encapsulation layer 19 flush with the active side 16 of the semiconductor chip 11a.

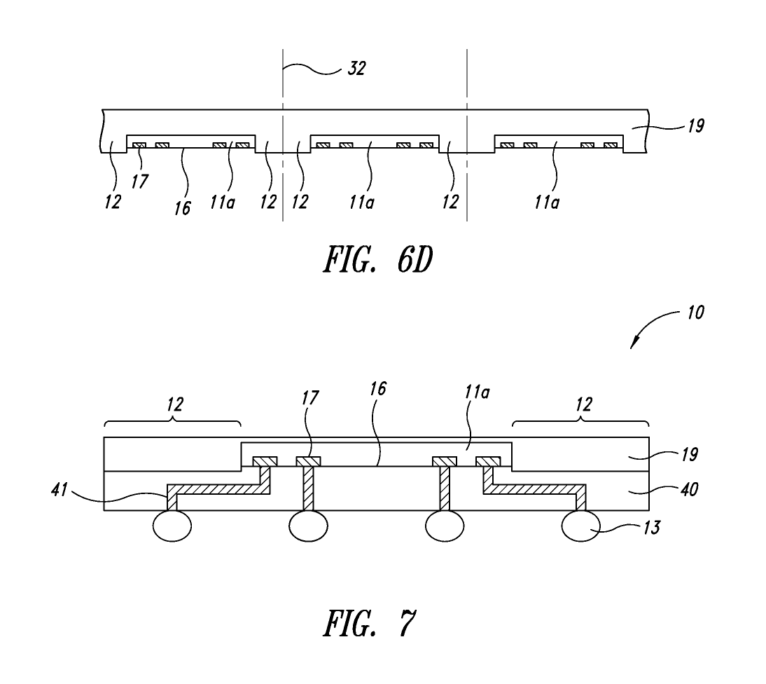

In an alternative embodiment, the passivation layer 15 is removed using an etching process. For example, dry plasma etching or wet plasma etching may be used to remove the passivation layer 15 and expose the active side 16 of the semiconductor chip 11a. If an etching process is used to remove the passivation layer 15, the encapsulation layer 19 may not be flush with the active side 16 of the semiconductor chip 11a. Despite this, the active side 16 of the semiconductor chip 11a may still be accessed and further processed as described with regard to FIG. 7.

In an additional embodiment, the encapsulation layer 19 may be ground down from the side of the semiconductor chip 11a opposite the active side 16. That is, the encapsulation layer 19 may be ground down to reduce the size of the semiconductor package 10. The encapsulation layer 19 may be ground down using CMP or the like.

FIG. 6D also shows locations 32 where the reconstituted wafer is cut to singulate the die. Once the reconstituted wafer has been formed as shown in FIG. 6D, the individual semiconductor packages may be cut from the reconstituted wafer at the singulation location 32. After the reconstituted wafer is cut at the singulation location 32, the semiconductor chips may be processed further and formed into the semiconductor package 10 as seen in FIGS. 1 and 7.

FIG. 7 shows a side view of the semiconductor package 10 with a semiconductor chip 11a that was formed using the process as shown and described with regard to FIGS. 6A-6D. The semiconductor chip 11a is enclosed by the encapsulation layer 19 and a bottom layer 40. According to one embodiment, a top layer (not shown) of the encapsulation layer 19 may be a heat sink that dissipates heat from the semiconductor chip 11a to the external environment of the semiconductor package 10. Additionally, the bottom layer 40 may be formed of an insulating substrate, such as silicon, that electrically insulates the semiconductor chip 11a and provides rigidity for the semiconductor package 10.

FIG. 7 also shows electrical contacts 13 attached to the bottom layer 40. The electrical contacts 13 may be solder balls or other electrically connecting material. To connect the semiconductor chip 11a to the external environment, the bottom layer 40 has electrical traces 41 embedded within to connect the semiconductor chip 11a to the electrical contacts 13. The embedded electrical traces 41 may be formed of various metals, such as copper, gold, titanium, etc.

In general, in the following claims, the terms used should not be construed to limit the claims to specific aspects of the disclosure described in the specification, but should be construed to include all possible aspects along with the full scope of equivalents to which such claims are entitled. Accordingly, the claims are not limited by the disclosure.

1. A method comprising:
exposing a passivation layer on a semiconductor wafer to ionized gas causing an exposed surface of the passivation layer to roughen;
cutting the semiconductor wafer into a plurality of semiconductor dies; and
affixing the plurality of semiconductor dies to an adhesion layer for forming a packaged semiconductor device, the exposed surface of the passivation layer being in contact with the adhesion layer.

2. The method of claim 1, wherein the ionized gas is produced in an ionization chamber.

3. The method of claim 1, wherein the ionized gas is any one of oxygen and tetrafluoride gases.

4. The method of claim 1, wherein the passivation layer is any one of silicon nitride, silicon dioxide, and oxynitride.

5. The method of claim 1, further comprising:
forming an encapsulation layer enclosing the adhesion layer and the plurality of semiconductor dies affixed to the adhesion layer.

6. The method of claim 1, wherein the ionized gas is produced using plasma etching.

7. The method of claim 6, wherein the plasma etching is one of reactive-ion etching and inductive coupled plasma etching.

8. The method of claim 1, wherein the adhesion layer comprises adhesive tape.

9. An integrated chip packaging system comprising:
a cutting device configured to cut a semiconductor wafer into a plurality of semiconductor dies;
an ionization chamber configured to expose a passivation surface of the semiconductor wafer to ionized gas; and
an affixing device configured to affix the plurality of semiconductor dies to an adhesion layer of a reconstituted wafer, the passivation surface of the plurality of semiconductor dies being in contact with the adhesion layer.

10. The integrated chip packaging system of claim 9, wherein the ionized gas is any one of oxygen and tetrafluoride gases.

11. The integrated chip packaging system of claim 9, wherein the passivation surface is part of a passivation layer comprised of any one of silicon nitride, silicon dioxide, and oxynitride.

12. The integrated chip packaging system of claim 9, wherein the ionized gas is produced using plasma etching.

13. The integrated chip packaging system of claim 12, wherein the plasma etching is one of reactive-ion etching and inductive coupled plasma etching.

14. The integrated chip packaging system of claim 11, further comprising:
a planarization device configured to remove the passivation layer.

15. The integrated chip packaging system of claim 14, wherein the passivation layer is removed using one of chemical mechanical planarization (“CMP”) and plasma etching.

16. A semiconductor package comprising:
a semiconductor die;
a passivation layer coupled to one side of the semiconductor die, the passivation layer having been subjected to ionized gas and forming a roughened surface on the passivation layer; and
an encapsulation layer enclosing at least two sides of the semiconductor die and leaving exposed the roughened surface of the passivation layer.

17. The semiconductor package of claim 16, wherein the ionized gas is one of oxygen and tetrafluoride.

18. The semiconductor package of claim 16, wherein the passivation layer is any one of silicon nitride, silicon dioxide, and oxynitride.

19. The semiconductor package of claim 16, further comprising:
electrical contacts coupled to the semiconductor die, the electrical contacts being configured to establish an electrical connection external to the semiconductor package.

20. The semiconductor package of claim 19, wherein the electrical contacts include solder balls.
